(19) United States
(12) Patent Application Publication
(10) Pub. No.: US 2007/0188778 A1
(43) Pub. Date: Aug. 16, 2007

(54) Method for controlling color on printing machines

(75) Inventor: Peter Schramm, Frankfurt (DE)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: MAN Roland Druckmaschinen AG, Offenbach (DE)

(21) Appl. No.: 10/589,296

(22) PCT Filed: Feb. 12, 2005
(86) PCT No.: PCT/EP05/01438

§ 371 Date: Aug. 14, 2006

(30) Foreign Application Priority Data
Feb. 28, 2004 (DE) 10 2004 009 271.0

(51) Int. Cl. G03F 3/08; G06F 15/00

(52) U.S. Cl. 358/1.9; 358/518

(57) ABSTRACT

A method for color correction in printing machines uses a learning process to determine the effects of changing colors. In a first stage of the method, the color supply of only a single process color is changed. The effect of changing the color supply of this one process color on the color values of a color spot to be measured is determined, and a corresponding chromaticity position is stored as a measurement value or measurement value set for this color. This-process can be performed separately one after the other for each individual process color involved in the autotype combination printing. In a second stage, all of the measurement values determined and stored earlier for all of the involved process colors are balanced with each other, such that for further color correction, a few or all of the process colors involved in the printing can be adjusted simultaneously.

The invention relates to a method for color correction in printing machines.

### BACKGROUND OF THE INVENTION

For proper execution of a print order it is necessary, among other things, to transfer the color index set for a product to be printed in a so called printing prepress stage correctly to a print material during the actual printing. For this purpose, usually the four scale colors, black, cyan, magenta, and yellow, as well as optionally also special colors are transferred in the form of halftone dots to the print material for autotype combination printing. The colors involved in autotype combination printing, namely the scale colors and the special colors, are also designated as process colors. For example, when printing, the halftone dots of the different colors can differ in size and the halftone dots of the different colors can be deposited on the print material with mutual overlap. From this it follows that the creation of a desired color effect is dependent on various factors and therefore is extremely complex.

A plurality of methods for color correction in printing machines is already known from the state of the art. The methods known from the state of the art for color correction usually provide several of the following disadvantages: a first disadvantage of methods known from the state of the art is that these methods require the so called area coverage of the colors involved in the print as measurement values for the color correction. The determination of the area coverage is very complicated and for the most part is only inexact, because usually the actual area coverage on the printed product differs from that on the printing plate and therefore can rarely be defined exactly, and because points important to the image for the most part involve areas that are not homogeneous in terms of color within a color spot to be measured. Therefore, methods for color correction that require area coverage as a calculation basis are, as a rule, inexact. Another disadvantage of methods known from the state of the art for color correction is that a few of the methods known from the state of the art require spectral color values as measurement values. The determination of spectral color values requires special measurement sensors, whereby the execution of such methods is complicated and expensive. Furthermore, large quantities of data must be processed for color correction methods that must rely on the determination of spectral color values. This is also complicated and expensive. Another disadvantage of methods known from the state of the art for color correction is that these methods are usually oriented only to the four scale colors of black, magenta, cyan, and yellow and are not in the position to control autotype combination printing with special colors. Furthermore, most of the methods known from the state of the art for color correction have considerable problems with correcting the color black. These are only a few of the disadvantages of methods known from the state of the art for color correction.

### SUMMARY OF THE INVENTION

Starting from this background, the present invention provides a novel method for color correction in printing machines.

According to the invention, the method comprises the following steps: a) for color correction, in a first step or in a first stage of the method, only the color supply of a single color, namely of a single process color, is changed, wherein here the effect of the change in the color supply of this one process color on the color values of a color spot to be measured is determined, with a corresponding chromaticity position being stored as a measurement value or measurement value set, and with this method being executed separately one after the other for each individual process color involved in the autotype combination printing; b) for color correction, in a second step or in a second stage of the method, all of the measurement values determined and stored in connection with step a) for all of the process colors involved in the autotype combination printing are balanced with each other, such that for further color correction, a few or all of the process colors involved in the printing can be set simultaneously.

In comparison with the methods known from the state of the art, the method according to the invention for color correction provides a plurality of advantages. It is not necessary for the method according to the invention to determine the so called area coverage, because this coverage is considered intrinsic to the method according to the invention. Furthermore, the method according to the invention touches on the measurement of so called standard color values, which enables a significant reduction of the quantities of data to be handled in comparison with the measurement of so called spectral color values. Furthermore, with the method according to the invention, in addition to the scale colors, also special colors and thus all of the process colors involved in the autotype combination printing are corrected reliably. The color black can also be corrected reliably, like all of the other process colors.

Examples of the invention will be explained in more detail with reference to the drawing, without limiting the invention to these embodiments.

### BRIEF DESCRIPTION OF THE DRAWINGS

FIG. 1 shows a signal flow chart for explaining the method according to the invention for color correction in printing machines; and

FIG. 2 shows a representation of the chromaticity position in the so called lab system for explaining the method according to the invention for color correction in printing machines.

### DETAILED DESCRIPTION OF THE EMBODIMENT

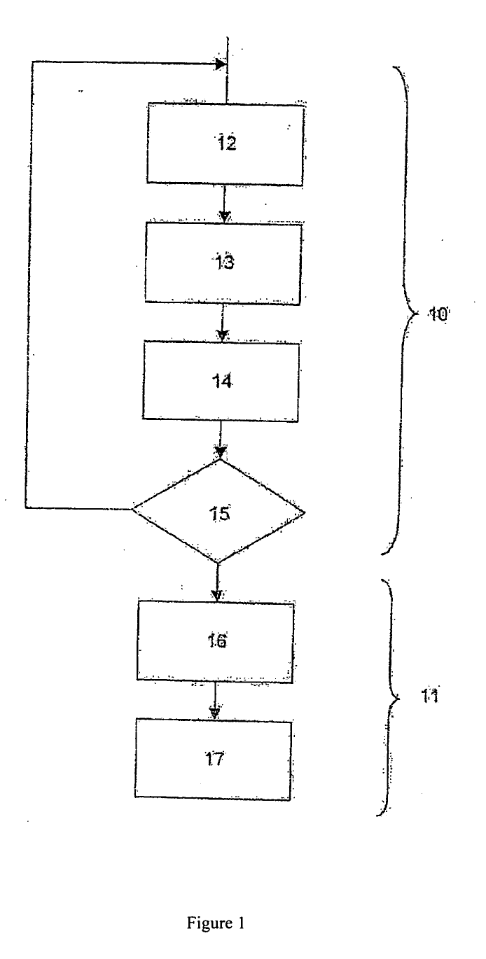

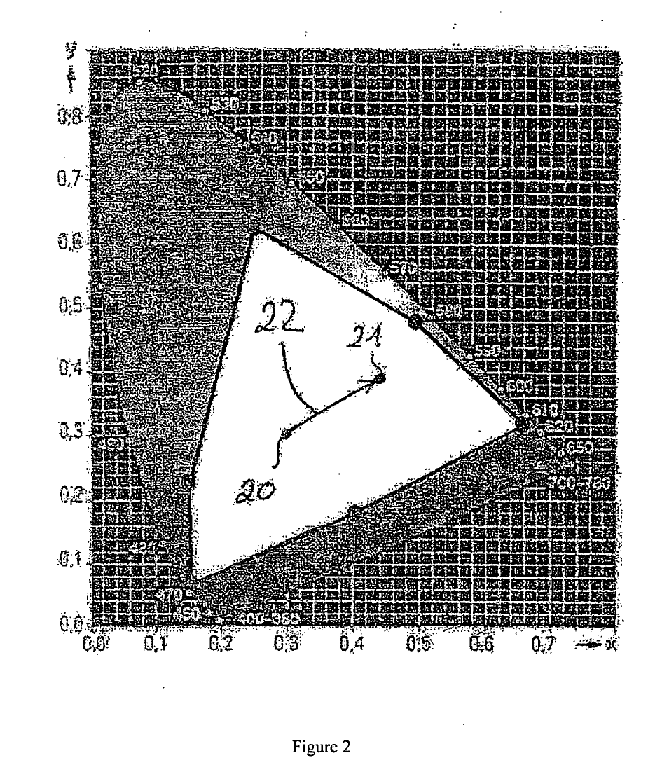

The method according to the invention is described below with reference to FIGS. 1 and 2 in greater detail.

In the method according to the invention for color correction, during the printing at least one color spot is measured online. In the following description, it is assumed that only one such color spot is measured, with this color spot involving a so called image important point of the print order.

In the measurement of the color spot, an actual chromaticity position is determined. The determined actual chromaticity position involves a measurement value set, which is composed of three color values, which are shown in a suitable system, preferably in the so called lab system.

The determined actual chromaticity position of the measured color spot is then compared with the corresponding desired chromaticity position for color correction. In this comparison, if it is determined that the actual chromaticity position corresponds to the desired chromaticity position or lies around this desired chromaticity position within certain tolerance limits, then printing can be continued without changing the process parameters. In contrast, if it is determined that the determined actual chromaticity position deviates from the corresponding desired chromaticity position, then color correction is performed.

The color correction according to the invention is performed in two stages or steps. FIG. 1 illustrates the two steps or stages 10, 11 of the method according to the invention.

In the first stage 10 of the color correction method according to the invention, according to block 12 first only the color supply of a single process color involved in the autotype combination printing is changed during the printing. Then, according to block 13, the effect of the change in the color supply of this one color on the color values of the color spot to be measured is determined. According to step 14, corresponding measurement values are stored that represent the effect of the adjustment of this one color on the color values of the chromaticity position.

After the color supply for a single process color is changed in the sense of blocks 12, 13, and 14 and the effect of this change on the color values of the chromaticity position of the color spot to be measured has been determined and stored, in step 15 it is tested whether through adjustment of the color supply of this one color the desired chromaticity position can been achieved. If this is the case, then control can be passed directly to block 16. However, if it is determined that the desired chromaticity position cannot be achieved, then it is further tested whether additional process colors are involved in the execution of the print order. Here, if it is determined that additional colors are present, for which the blocks 12, 13, and 14 have not yet been performed, then control passes back to block 12 and the effect of a change in the color supply of one color on the color values of the chromaticity position is determined for each individual process color separately and independently of the other process colors.

The first step or the first stage 10 of the method according to the invention for color correction represents a learning stage, as it were, in which the effect of changing a single process color is determined. In block 15, as soon as it is determined that the blocks 12, 13, and 14 have been processed for every process color involved in the printing, control passes to block 16, that is, the second stage 11 of the method according to the invention.

In block 16 of the second stage 11 of the method according to the invention, all of the measurement values determined and stored in the first stage 10 in terms of all of the process colors involved in printing are balanced with each other, so that for further color correction, a few or all of the colors involved in printing can be adjusted simultaneously. After ending the first stage 10, that is, the learning stage, it is known, namely, which effects the adjustment of each process color has on the chromaticity position. From these values, it can then be determined through mathematical calculations, which effect the simultaneous adjustment of several process colors involved in the autotype combination printing has on the chromaticity position.

It should be mentioned at this point that it is determined in the first stage 10 of the method according to the invention how the chromaticity position changes when each individual color in the corresponding color system, especially in the lab system, is changed. This can be taken from FIG. 2, in which the measured chromaticity position is labeled with the reference symbol 20 before the adjustment of a color and with the reference symbol 21 after adjustment of this color. Thus, in the lab system of FIG. 2, the chromaticity position 20 is characterized by coordinates (0, 3; 0, 3) and the chromaticity position 21 is characterized by coordinates (0, 42; 0, 38). Through these coordinates, a color vector 22 is defined, which is characteristic for the effect of the change of one color on the color values of the color spot to be measured, and which is stored as a corresponding measurement value set or as the chromaticity position for this color. Preferably, in the first stage 10 of the method, such a color vector is determined for each process color involved in the printing.

Then, in the second stage 11 of the method, through simple vector addition of the color vectors determined in the first stage 10, the effect of the simultaneous change of several colors on the chromaticity position can be calculated.

It should be mentioned that the effect of changing the color supply of each individual color on the chromaticity position in the sense of the first stage 10 of the method according to the invention can be determined using two different means and ways. Thus, according to a first alternative of the method according to the invention, by adjusting the color supply of a single color, control can wait until the color is in balance after the adjustment. After reaching this balanced stage, then the change of the chromaticity position caused by the adjustment of the color is determined as a corresponding color vector. Alternatively, it is also possible to determine one measurement value set after a certain time period or several measurement value sets at certain time intervals and then to lock onto the changing balanced state through extrapolation. The extrapolation provides the advantage that corresponding measurement values can be determined significantly faster than in the case in which control waits until reaching a balanced state.

Subsequent to block 16, in block 17 preferably the result set on the basis of the correction performed in block 16 is tested. Here, it is tested whether the color values of the chromaticity position set after the correction correspond to the result pre calculated in block 16. Here, if there is a considerable deviation, then the vector addition performed in block 16 can be modified, for example, so that the direction and magnitude of the individual vectors can be corrected on the basis of the present result.

The learning phase 10 of the method according to the invention is preferably run only once by printing a print order. If correction deviations occur when this same print order is executed, then the correction can be performed on the basis of the parameters learned in stage 10. The desired color values required for correction can be known either from the pre printing stage and provided automatically to the method according to the invention as input parameters, or can be determined in the course of a manual or correction system supported setup phase of the printing machine.

At this point it should be mentioned that obviously also after adjusting the color supply of a single process color, the desired result, that is, the desired chromaticity position, can be achieved. In this case, in the first stage 10, first only the color vector for this one color is determined and then switched to the second stage 11. However, in the course of the print order if it comes to light that the desired chromaticity position cannot be achieved by adjusting this one color, then control can pass back to the first stage 10 and the learning step for one or more other process colors can be performed.

With the aid of the method according to the invention, an especially simple color correction in printing machines is possible. The method according to the invention is divided, in principle, into two stages, namely a learning stage and also the actual correction stage. In the learning stage, the color supply is set individually for each process color involved in the printing and the changing effect on the chromaticity position can be determined using vectors. After this has been performed separately for each process color involved in the printing, in a second stage of the method according to the invention, these determined, vectorized parameters are superimposed through vector addition, in order to pre calculate the effect of a simultaneous adjustment of several or all of the colors involved in the printing.

For the correction method according to the invention, no area coverage need be determined, because this is inherently taken into consideration. With the method according to the invention, scale colors and special colors involved in the autotype combination printing can be corrected reliably and equally. Because the method according to the invention involves the determination of standard color values, it can be executed with low computational expense.

1-7. (canceled)

8. A method for color correction in printing machines, comprising:
(a) executing separately one after the other for individual process colors involved in an autotype combination printing; changing only the color supply of a single process color; determining the effect of the change in the color supply of this one process color on color values of a color spot to be measured; and storing a corresponding color spot for this color;
(b) balancing all of the measurement values determined and stored in step (a) with each other so that for further color correction, a few or all of the process colors involved in the printing can be adjusted simultaneously.

9. A method according to claim 8, wherein during the printing at least one color spot is measured, wherein for this measurement at least one actual chromaticity position is determined, and that the actual chromaticity position or each actual chromaticity position is compared with a corresponding desired chromaticity position, wherein the color correction is performed when the actual chromaticity position deviates from the corresponding desired chromaticity position.

10. 3. A method according to claim 8, wherein for determining the measurement values of the chromaticity position or each chromaticity position, control waits in step a) until a balanced state has been reached after a color supply of the corresponding color to be printed has been changed.

11. A method according to claim 8, wherein for determining the measurement values of the chromaticity position or each chromaticity position in step a), at least one value is measured after a certain time period or at certain time intervals and control locks the changing balanced state through extrapolation.

12. A method according to one or more of claim 8, wherein in step (a), for each process color to be printed, the effect of the isolated change in a color supply of each process color on the chromaticity position of the color spot to be measured, is measured separately one after the other in time.

13. A method according to claim 12, wherein it is determined how the corresponding chromaticity position shifts when changing the color supply of each process color, and that the magnitude and direction of a color vector are determined from the chromaticity positions before the color change and after the color change.

14. A method according to one or more of claims 1, characterized in that the determined and stored measurement values according to step (b) are balanced through vector operations.
